(19) United States
(12) Patent Application Publication
(10) Pub. No.: US 2007/0074968 A1
(43) Pub. Date: Apr. 5, 2007

(54) ICP source for iPVD for uniform plasma in combination high pressure deposition and low pressure etch process

(76) Inventor: Mirko Vukovic, Slingerlands, NY (US)

Correspondence Address: WOOD, HERRON & EVANS, LLP (TOKYO ELECTRON), 2700 CAREW TOWER, 441 VINE STREET, CINCINNATI, OH, 45202, US

(21) Appl. No.: 11/240,670

(22) Filed: Sep. 30, 2005

(51) Int. Cl. C23C 14/32; C23C 14/00

(52) U.S. Cl. 204/192.1; 204/298.01

(57) ABSTRACT

A system and method is provided for using an ionized physical vapor deposition (iPVD) source for uniform metal deposition having uniform plasma density at relatively low (5 mTorr) and relatively high (65 mTorr) operation. Magnet structure is combined with an inductively coupled plasma (ICP) source to shift the plasma toward the chamber periphery during low pressure operation to enhance uniformity, while plasma uniformity is promoted by randomization or thermalization of the plasma at higher pressures. Accordingly, uniformity is provided for both deposition and etching in combined sequential deposition-etch processes and for no-net-deposition (NND) and low-net-deposition (LND) deposition-etching processes.

This invention relates to inductively coupled plasma (ICP) sources for use in the manufacture of semiconductor wafers. This invention particularly relates to relatively high pressure ionized physical vapor deposition (iPVD) and relatively low pressure etch sequential processes and systems where plasma uniformity is desirable over a wide pressure range as well as deposition and etching processes that result in no-net-deposition (NND) or low-net-deposition (LND).

### BACKGROUND OF THE INVENTION

For the deposition of films onto high aspect ratio, submicron-featured semiconductor wafers, ionized physical vapor deposition (iPVD) has proved most useful. Apparatus having the features described in U.S. Pat. Nos. 6,287,435, 6,080,287, 6,197,165, 6,132,564 are particularly well suited for the sequential or simultaneous deposition and etching processes. Sequential deposition and etching processes can be applied to a substrate in the same process chamber without breaking vacuum or moving the wafer from chamber to chamber. The configuration of the apparatus allows rapid change from ionized PVD mode to etching mode or from etching mode to ionized PVD mode. The configuration of the apparatus also allows for the simultaneous optimization of ionized PVD process control parameters during the deposition mode and etching process control parameters during the etching mode.

Of the advantages of ionized PVD systems, there are still some constraints to utilization of the system at the maximum of its performance. For example, existing hardware does not allow optimizing uniformity for both deposition and etch processes simultaneously over a wide process pressure window. While an annular target provides excellent conditions for flat field deposition uniformity, the use of large area inductively coupled plasma (ICP) to generate a large size low-pressure plasma for uniform etch process is geometrically limited. While an ICP source that is axially aligned with the substrate is optimal to ionize metal vapor sputtered from a target and to fill features in the center of a wafer, it can produce an axially peaked high-density plasma profile that does not provide a uniform etch in a combined deposition and etch process or in a no-net-deposition (NND) process or low-net-deposition (LND) process. In these processes, etching occurs at an increased bias at the wafer so deposited metal is simultaneously removed from the flat field area of the wafer during deposition while remaining deposited at the sidewalls of the feature. The net process leaves the deposition of a thin film at the bottom of the feature.

The iPVD source of U.S. Pat. No. 6,080,287 provides a high metal ionization fraction and uniform metal deposition. Etching can be combined with iPVD processes as in U.S. Pat. No. 6,755,945 . When this combination is used to produce low-net-deposition or no-net-deposition processes, either a continuous or pulsed process step of sputter-etching of the wafer can be used. However, with a compact and centrally located RF coil and baffle, a non-uniform plasma can result during etching due to the tendency of the plasma to concentrate toward the chamber center at the lower pressures that are typically preferred for etching.

Researchers have investigated the effects of chamber geometry and pressure on the plasma profile in an inductively coupled plasma source. To achieve a uniform plasma profile at high pressure (several tens of mTorr), RF coils have been placed toward the periphery of the cylindrical chamber. It has been also shown that, during low pressure operation, the plasma profile tends to be domed irrespective of the location of the RF coils, with the edge-to-center plasma density ratio being about 0.4 - 0.5.

Accordingly, there remains a need to provide an iPVD source that can generate a uniform plasma at both relatively low pressures (e.g., at about 5 mTorr) for sputter-etch and relatively high (e.g., at about 65 mTorr) pressures for uniform metal deposition and for LND and NND processes at some common pressure, often but not necessarily, in the range of 20 - 60 mTorr.

### SUMMARY OF THE INVENTION

An objective of the present invention is to provide an iPVD source that can generate a uniform plasma at both relatively low pressures and relatively high pressures.

A further objective of the invention is to provide a uniform plasma for metal deposition for sputter-etching.

In accordance principles of the present invention, an iPVD source is provided with an ICP antenna and a peripheral magnetic field configured to trap high energy electrons towards the chamber periphery, thereby reducing the concentration of high energy electrons at the chamber center at lower chamber pressures or during etching, and reduce chamber diameter. Embodiments of the invention employ the peripheral magnetic field to improve plasma uniformity iPVD and etching processes, particularly in sequential deposition and etching processes.

These and other objects and advantages of the present invention will be more readily apparent from the following detailed description of illustrated embodiments of the invention.

### BRIEF DESCRIPTION OF THE DRAWINGS

FIG. 1 is cut-away perspective view of a processing apparatus having a source according to one embodiment of the invention.

FIG. 2 is cut-away perspective view of a portion of a deposition baffle of the source of the processing apparatus of FIG. 1.

FIG. 3 is diagrammatic perspective view illustrating a cooling channel configuration for the baffle of FIG. 2.

FIG. 4 is a cross-sectional view through a portion of FIG. 1 illustrating the baffle of FIG. 2.

FIG. 5 is a perspective view illustrating an alternative magnet configuration to the embodiment shown in FIG. 1.

### DETAILED DESCRIPTION

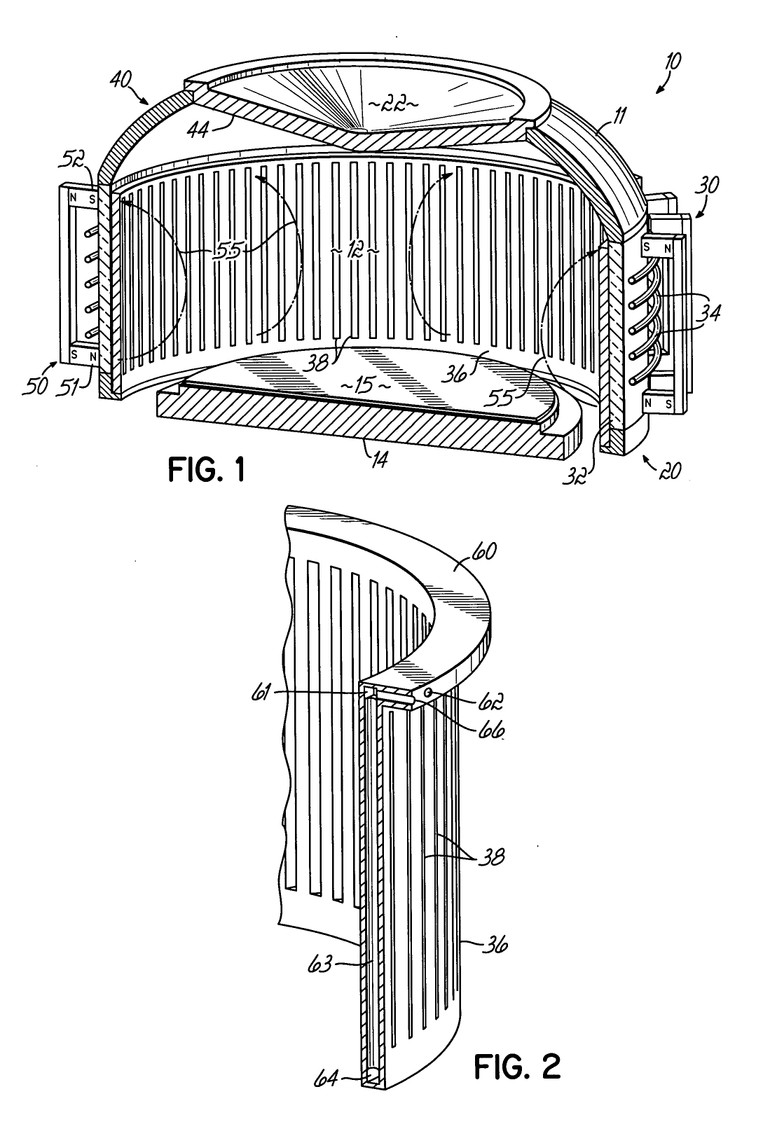

One embodiment of an iPVD processing apparatus 10 is illustrated in FIG. 1. The apparatus 10 includes a vacuum processing chamber 12 having a wafer support 14 at the bottom thereof for supporting a wafer 15 thereon for processing, and a source 20 that includes a plasma source 30 and coating material source 40. The coating material source 40 includes a sputtering target 42 at the top of the chamber 12 and having a sputtering surface 44 in communication with the vacuum chamber 12. The target 42 is mounted in an opening in a chamber wall 11 that encloses the chamber 12 and which is either non-electrically-conductive or insulated form the target 42. A target cooling system (not shown) is typically also provided. The material source 40 may also include magnetron magnets (not shown) on the top (back) side of the target 42, which may including fixed or moving magnets such as rotating magnets. The material source 40 is also provided with a sputtering power source (also not shown) of typically DC electrical energy to form a sputtering plasma confined closely to the sputtering surface 44 of the target 42.

The plasma source 30 includes a dielectric window 32 which forms the cylindrical side-wall portion of the chamber wall 11, an RF antenna 34, shown as a helical coil that surrounds the outside of the dielectric window 32, and a cylindrical axially-slotted, electrically-conductive deposition baffle 36, which shields the dielectric window 32 from contamination by coating material from within the chamber 12. The antenna 34 is configured to inductively couple RF energy into the chamber 12 to form a high density plasma in the chamber 12.

The plasma source 30 has spaced around the outer periphery of the plasma source 30 outside of the chamber 12 an array of magnets 50. In the illustrated embodiment, the magnets 50 are closely spaced circumferentially around the chamber 12 with opposing poles 51 and 52, with the polar axes of the magnets extending axially between their respective poles and aligned in the same direction to enclose within a magnetic field 70, extending between the poles 51 and 52, portions of the chamber wall 11 at the dielectric window 32. The magnets 50 may be formed, for example, in a horseshoe shape and include a pair of bar magnets 53 and 54, each having a pair of poles arranged such that one of the poles is a respective one of the poles 51 or 52 located close to the dielectric window 32, with the other of the poles being adjacent a bar of magnetic core material 56. The magnets 50 are preferably RF shielded by a thin copper, silver or nickel layer, and at least air cooled. The magnets 50 may also be provided with a cooling system (not shown). For example, the magnets 50 may be placed inside of or proximate to a water jacket.

In the embodiment illustrated in FIG. 1, a permanent magnetic field 70 extends axially between the poles 51,52, arcing around the conductors of the antenna 34 inside of the chamber 12 and inside the shield 36, forming a circumferential magnetic tunnel around the inside of the window 32. It is believed that, at low pressures, at the levels used for etching in particular, for example below about 20 mTorr, the magnetic field captures energetic electrons near the coil 34, and deters them from flowing across the chamber 12 where they might concentrate near the center of the chamber 12. These electrons would then do their ionizing more at the chamber periphery. This edge-weighted ionization would provide a more uniform plasma distribution throughout the chamber 12, with the plasma ion density less domed or concentrated at the center.

It is further believed that, at higher pressures, at the levels used for iPVD in particular, for example at pressures above about 30 mTorr, the frequent collisions randomize the electron motion sufficiently, so they do not feel the effects of the magnetic field and the plasma density distribution remains unchanged by the addition of the magnet assemblies. However, in that case, it would be the frequency of collisions with the background gas that would keep the energetic electrons from streaming across the chamber 12 from the region near the coil toward the chamber center. Instead, they would do a random walk that would eventually lead them throughout the chamber, but at such a slow pace that they would dissipate most of their energy near the coil, again providing an edge enhanced ionization.

If a lower pressure coating process is employed or if there are other reasons for removing the magnetic field during deposition, permanent magnets or parts thereof can be made moveable to switch into or out of position during etching and deposition respectively. However, the presence of the magnets during higher pressure iPVD processes is unlikely to be detrimental and should in many cases be beneficial. The magnetic field strength should be at least about 50 Gauss, for example, up to 200 Gauss or above.

The presence of a magnetic field near the coil 34, rather than the field's configuration, should provide similar advantages described above. For example, a magnet 55a made up of segments as illustrated in FIG. 5 can be provided around the chamber 12, spaced outward so that its field 55a produces an array of magnetic cusps defining axially oriented tunnels that enclose a more limited portion of the coil 34. The field of magnet 55a would have some effect within the chamber 12 of retaining electrons near the inside of the window 32 inside the shield 36 so as to flatten the plasma at lower pressures. Other magnet configurations can be used to produce a plasma flattening effect.

As designed, the maximum radius of the source 20, for wafers up to 30 cm in diameter, can be 50.5 cm, which is considerably less than many current iPVD modules. Such a source 20 may include targets of various shapes, including planar targets and inverted frusto-conical targets. Frusto-conical targets having cone angles of approximately 10 degrees to the horizontal are expected to be particularly useful. The size of the current iPVD module was driven by the desire to keep the plasma as uniform as possible above the wafer, and to reduce the radial ambipolar electric field. In order to achieve that goal, a large empty space was provided around the wafer 15. With sources 20 according to the above described embodiment of the present invention, the plasma is uniform by design, and the radial ambipolar electric field is very small. The only constraint on the radius of the chamber is metal transport and loss to the wall, where reduction in the chamber diameter increases the fraction of the metal that is deposited on the baffle.

Because of the smaller processing volume, the required RF power can be less than the 5.5 kWatt, which is typical in current iPVD systems. The smaller size also reduces coil inductance, making operation at 13.56 MHz easier to attain. The number of turns of the coil or antenna 34 can also be optimized. Operation at 2 MHz is expected to be particularly useful.

The baffle 36 is preferably provided with slots 38 having chevron-shaped cross-sections to impede the flow of coating material through the slots 38 to the window 32. The cylindrical baffle 36 has a much larger surface area than the circular baffles used with sources having antennas at an end of the chamber. This, combined with the reduced power flow through it reduces the heat load on the baffle 32. Such a baffle 32 can be adequately cooled by contact with a cold sink, which can be part of the chamber wall. Optionally, the baffle can be cooled by water flow through channels along the baffle top and bottom, as illustrated in FIG. 2.

The baffle 36 can also be provided with an upper support flange 60 which connects the baffle 36 at the chamber wall 11, as illustrated in FIG. 4. At the wall 11, the baffle 36 may be insulated from or electrically connected to the wall 11, depending on whether the baffle 36 is to be maintained at a potential different than the chamber wall 11. Typically, the baffle flange 60 is between the window 32 and the wall 11 and is well RF grounded from the chamber wall 11.

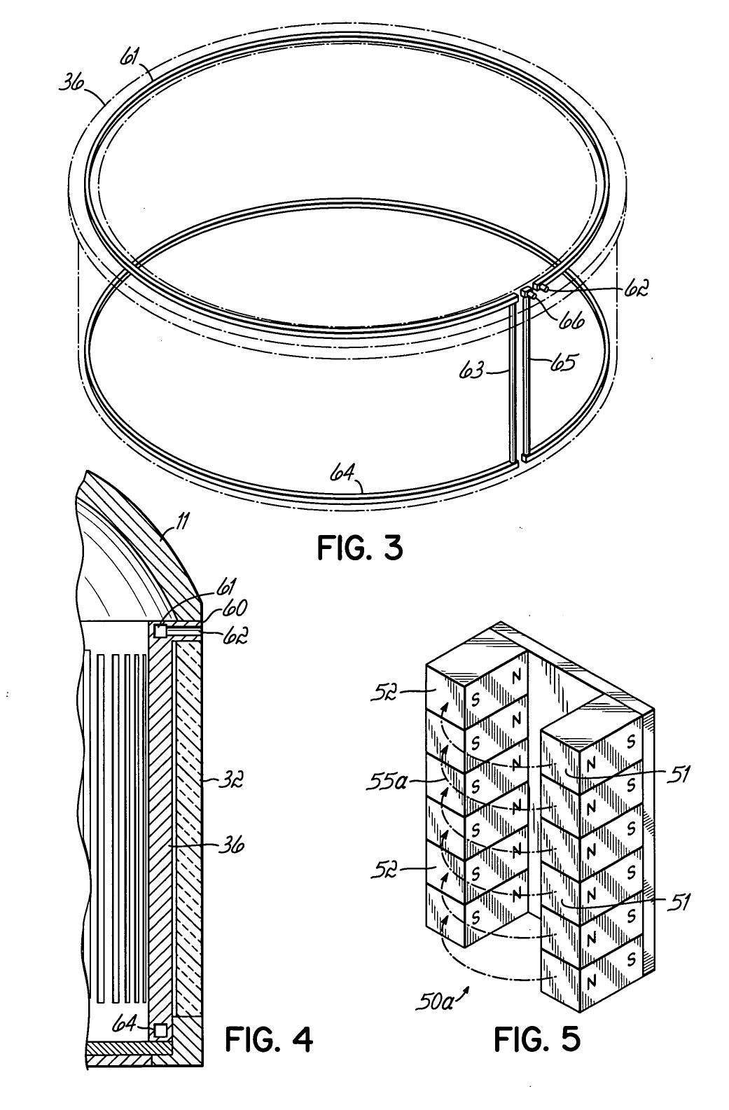

The flange 60 has an upper cooling fluid channel 61 around the top thereof to which liquid cooling fluid is supplied through an inlet 62. The channel 61 is connected through a vertical channel 63 between two of the slots 38 in series with a lower cooling fluid channel 64 in the bottom rim of the baffle 36, as illustrated in FIG. 3. The lower channel 64 connects further through another vertical channel 65 between a different two slots 38 to a fluid outlet 66 in the rim 60. With the inlet 61 and outlet 66 in the rim of the flange 60, the water or other liquid feed can be in atmosphere at standard pressure rather than in the vacuum of the chamber 12. Water first flows in the inlet 62 and through the upper ring 61 of the baffle, then to to the lower ring 64 along vertical channel 63 in one of the baffle ribs. After completing the traversal of the lower ring 64, the water flows along vertical channel 65 to the top ring 61, where it finally flows out of the baffle 36 via outlet 66.

The source 20 needs no chamber shields. Instead the exposed portions of the wall 11 can be made of aluminum and be water cooled, with the inside surface thereof treated to promote material adhesion. The wall 11 can then be periodically cleaned, which is usually done by replacing the wall with a cleaned wall and sending the removed wall out for cleaning and reconditioning.

This source 20 has several advantages from the point of view of maintenance. The target 42 is decoupled from the RF source 30. Thus, changing the target 42 is much simpler, and much quicker than with a design in which the plasma and material sources are combined. Similarly, the chamber wall 11 can be removed and cleaned. Also, the parts are sufficiently light to eliminate the need for a hoist to remove and replace a target. The small footprint and simple coil design also reduce costs.

Examples of semiconductor wafer processing machines of the iPVD type are described in U.S. Pat. Nos. 6,080,287, 6,287,435 and 6,719,886. Embodiments of the present invention are described in the context of the apparatus 10 of FIG. 1, even though applicable to other types of systems.

Although only certain exemplary embodiments of this invention have been describe in detail above, those skilled in the art will readily appreciate that many modifications are possible in the exemplary embodiments without materially departing from the novel teachings and advantages of this invention. Accordingly, all such modifications are intended to be included within the scope of this invention.

What is claimed is:

1. A method of depositing a film onto high aspect ratio, submicron-featured semiconductor wafers, the method comprising:
processing a semiconductor wafer sequentially in a plurality of processes in a vacuum processing chamber, the processes including an ionized physical vapor deposition (iPVD) process and a sputter etching process;
the iPVD process including:
sputtering coating material from the target into a processing space within the vacuum processing chamber,
forming a high density plasma by coupling RF energy from the antenna into the processing space,
ionizing the sputted coating material in the plasma in the processing space, and
depositing ionized sputtered material from the processing space onto a substrate; and
the etching process including:
forming a high density plasma by coupling RF energy from the antenna into the processing space,
ionizing a processing gas in the plasma in the processing space,
magnetically confining at least some of the plasma near the perimeter of the processing chamber, and
etching the substrate on the substrate support with the ionized processing gas.

2. The method of claim 1 wherein:
the deposition process and the etching process are performed sequentially.

3. The method of claim 1 wherein:
the deposition process and the etching process are performed simultaneously.

4. The method of claim 1 wherein:
the deposition process and the etching process are performed simultaneously so as to result in no net deposition on flat field areas of the substrate.

5. The method of claim 1 wherein:
the deposition process and the etching process are performed simultaneously so as to result in low net deposition on flat field areas of the substrate.

6. The method of claim 1 wherein:
the magnetic confining of at least some of the plasma near the perimeter of the processing chamber during the etching process is achieved by providing magnets around the perimeter of the chamber during both the deposition and etching processes.

7. The method of claim 1 further comprising:
maintaining the chamber at a first pressure during the deposition process and maintaining the chamber at a second and lower pressure during the etching process.

8. The method of claim 7 wherein:
the first pressure is at least 30 mTorr and the second pressure is less than 10 mTorr.

9. The method of claim 7 wherein:
the first pressure is approximately 65 mTorr and the second pressure is approximately 5 mTorr.

10. An iPVD semiconductor wafer processing apparatus comprising:
a vacuum processing chamber having two ends and a sidewall around a periphery of the chamber;
a sputtering target in the chamber at one end of the chamber;
a substrate support at the other end of the chamber;
a high-density plasma source having an antenna surrounding the sidewall of the chamber;
a permanent magnet assembly outside of the sidewall of the chamber having opposite magnet poles positioned relative to the sidewall so as to extend a magnetic field over one or more magnetically defined regions to urge electrons toward the periphery of the chamber; and
a controller programmed to sputter, ionize and deposit material from the target onto the substrate by an iPVD process and to etch at least some of the deposited material from the substrate.

11. The apparatus of claim 10 wherein:
the controller is programmed to operate the apparatus in a plurality of modes, including a deposition mode and an etch mode;
the deposition mode including sputtering coating material from the target into a processing space within the vacuum processing chamber, forming a high density plasma by coupling RF energy from the antenna into the processing space, ionizing the sputted coating material in the plasma in the processing space, and depositing ionized sputtered material from the processing space onto a substrate on the substrate support; and
the etch mode including forming a high density plasma by coupling RF energy from the antenna into the processing space, ionizing a processing gas in the plasma in the processing space, and etching the substrate on the substrate support with the ionized processing gas.

12. The apparatus of claim 11 wherein:
the deposition mode includes maintaining a pressure in the processing space at not less than 30 mTorr during the deposition mode; and
the etch mode includes maintaining a pressure in the processing space at not more than 10 mTorr during the etch mode.

13. The apparatus of claim 10 wherein:
the controller is programmed to operate the apparatus in a plurality of modes, including a first mode and a second mode;
the first mode including maintaining a pressure in the processing space at not less than 30 mTorr; and
the second mode including maintaining a pressure in the processing space at not more than 10 mTorr.

14. The apparatus of claim 10 wherein:
the permanent magnet assembly includes a plurality of magnets each having spaced north and south poles axially aligned and oriented in the same direction to produce a magnetic tunnel extending circumferentially around the perimeter of the chamber inside of the chamber wall.

15. The apparatus of claim 10 wherein:
the magnetic field surrounds at least a portion of the antenna.

16. In an iPVD source for use in a deposition-etch process, providing an ICP antenna and a peripheral magnetic field configured to shift electron concentration toward the chamber periphery, thereby reducing the concentration of plasma at the chamber center at lower chamber pressures or during etching.

17. In the iPVD source of claim 16 wherein the deposition-etch process is a no-net-deposition (NND) process.

18. In the iPVD source of claim 16 wherein the deposition-etch process is a low-net-deposition (LND) process.

19. In the iPVD source of claim 16 wherein the sequential deposition-etch process.

20. In the iPVD source of claim 16 wherein the sequential deposition-etch process having a deposition portion followed by an etch portion in which the deposition portion is performed at a higher pressure than the etch portion.
